(19) United States
(12) Patent Application Publication
(10) Pub. No.: US 2026/0082916 A1
(43) Pub. Date: Mar. 19, 2026

(54) PACKAGE-ON-PACKAGE STRUCTURE INCLUDING MULTI-PHASE COOLING STRUCTURE

(71) Applicant: QUALCOMM Incorporated, San Diego, CA (US)

(72) Inventors: Le GAO, San Diego, CA (US); Youmin YU, Escondido, CA (US); Nader NIKFAR, San Diego, CA (US)

(21) Appl. No.: 18/889,749

(22) Filed: Sep. 19, 2024

(51) Int. Cl. H01L 23/427; H01L 23/538; H01L 25/00; H01L 25/18; H10B 80/00

(52) U.S. Cl. CPC H10W 40/73; H10W 70/60; H10W 70/611; H10W 90/00; H10B 80/00

(57) ABSTRACT

A package-on-package (PoP) structure is disclosed comprising a first package, a second package overlying and electrically coupled with the first package, and a multi-phase cooling structure disposed between and in contact with the first package and the second package.

### FIELD OF DISCLOSURE

The present disclosure generally relates to integrated circuit technology, and more particularly, to thermal dissipation of heat generated in a package-on-package (PoP) structure.

### BACKGROUND

Integrated circuit (IC) technology has achieved great strides in advancing computing power through miniaturization of electrical components. An IC may be implemented in the form of an IC chip that has a set of circuits integrated thereon. In some implementations, one or more IC chips can be physically carried and protected by an IC package, where various power and signal nodes of the one or more IC chips can be electrically coupled to respective conductive terminals of the IC package via electrical paths formed in a package substrate of the IC package. Various packaging technologies can be found in many electronic devices, including processors, servers, radio frequency (RF) integrated circuits, etc. Advanced packaging and processing techniques can be used to implement complex devices, such as multi-electronic component devices and system-on-chip (SOC) devices, which may include multiple function blocks, with each function block designed to perform a specific function, such as, for example, a microprocessor function, a graphics processing unit (GPU) function, a communications function (e.g., WiFi, Bluetooth, and other communications), and the like.

As these circuits become more complex and densely packed, they inherently generate a significant amount of heat during operation. This heat generation poses serious challenges that can impact the performance, reliability, and lifespan of the ICs. For ICs comprising single dies, the heat generated is primarily a result of the active transistors within the circuit. As the number of transistors on a single die increases, however, so does the heat generated. Package-on-Package (PoP) structures present an even more complex thermal dissipation challenge. Stacking packages increases the density of the components, leading to even higher heat generation. The proximity of the packages in a stacked configuration can hinder effective heat dissipation, causing heat to accumulate within as well as between the packages.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an electronic device includes a package-on-package (PoP) structure comprising: a first package; a second package overlying and electrically coupled with the first package; and a multi-phase cooling structure disposed between and in contact with the first package and the second package.

In an aspect, a package-on-package (PoP) structure comprising: a first package; a second package overlying and electrically coupled with the first package; and a multi-phase cooling structure disposed between and in contact with the first package and the second package.

In an aspect, a method of forming a package-on-package (PoP) structure includes forming a first package; forming a second package overlying and electrically coupled with the first package; and forming a multi-phase cooling structure disposed between and in contact with the first package and the second package.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1 shows an example of a package-on-package (PoP) structure, according to aspects of the disclosure.

FIG. 2 shows an example of a PoP structure having thermal dissipation augmented by a multi-phase cooling structure, according to aspects of the disclosure.

FIG. 3A through FIG. 3E shows example processing operations that may be undertaken to form a PoP structure having augmented heat dissipation, according to aspects of the disclosure.

FIG. 4 shows an example of a multi-phase cooling structure, according to aspects of the disclosure.

FIG. 5 shows another example of a multi-phase cooling structure, according to aspects of the disclosure.

FIG. 6 illustrates an example of a relationship between certain components used to construct a PoP structure, according to aspects of the disclosure.

FIG. 7 illustrates another example of the relationship between certain components used to construct a PoP structure, according to aspects of the disclosure.

FIG. 8 is a method showing example processing steps that may be used to construct a PoP structure, according to aspects of the disclosure.

FIG. 9 illustrates a profile view of a package that includes a surface mount substrate, an integrated device, and an integrated passive device, according to aspects of the disclosure.

FIG. 10 illustrates an example method for providing or fabricating a package that includes an integrated device comprising an electronic component mounted in a core, according to aspects of the disclosure.

FIG. 11 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC).

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

There is a need for enhanced thermal dissipation designs to support the continued trend toward vertical IC expansion and to improve the performance of three-dimensional (3D) designs by providing additional thermal headroom. The key to optimizing thermal dissipation lies in effectively managing heat dissipation within package-on-package (PoP) structures. Greater dissipation efficiency can be achieved when the heat dissipation prevents the formation of concentrated hot spots. Thermal dissipation of heat generated in PoP structures improves overall system performance and reliability.

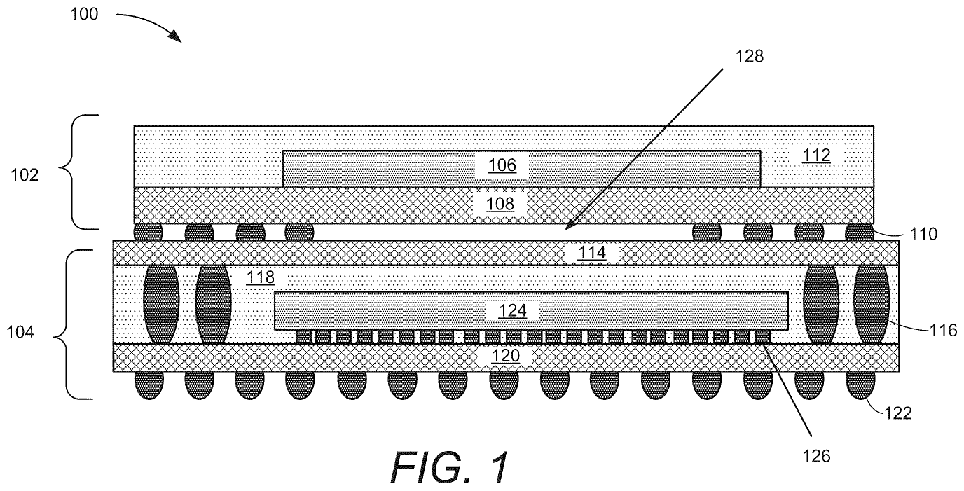

FIG. 1 shows an example of a package-on-package (PoP) structure 100, according to aspects of the disclosure. For simplicity, the patterned metallization layers disposed over various surfaces of the components of the PoP structure 100 as well as any via structures extending through any substrate have been omitted from the figures. However, the placement and patterning of such patterned metallization layers and via structures is well-known and their placement in the context of the PoP structure varies based on design specifications.

In this example, the PoP structure 100 includes an upper package 102 and a lower package 104. In an aspect, the upper package 102 may include a die 106 that is electrically coupled to one or more patterned metallization layers overlying a substrate 108. In an aspect, the substrate 108 may include via structures that electrically couple the patterned metallization layers overlying the substrate 108 to interconnect joints 110 disposed at a lower surface of the substrate 108. In an aspect, the lower surface of the substrate 108 may include one or more patterned metallization layers. These conductive structures electrically couple the die 106 with the interconnect joints 110. In an aspect, a molding compound 112 may be formed over the die 106 and the upper surface of the substrate 108.

Similarly, the lower package 104 may include an interposer substrate 114 having one or more patterned metallization layers disposed over the upper surface of the interposer substrate electrically coupled to the interconnect joints 110. Another patterned metallization layer may be formed on the lower surface of interposer substrate 114. In an aspect, the interposer substrate 114 may have one or more via structures that electrically couple the patterned metallization layer overlying the interposer substrate 114 to via structures 116 that extend through a molding compound 118 to a patterned metallization layer formed over the upper surface of substrate 120. In an aspect, the metallization layer formed over the upper surface of the substrate 120 may be electrically coupled to a patterned metallization layer formed over a lower surface of the substrate 120, thereby providing electrically conductive paths between the die 106 and interconnect joints 122 disposed at a lower surface of the substrate 120.

In an aspect, the lower package 104 may include a die 124 having interconnect joints 126 that electrically couple the die 124 to the patterned metallization layer disposed over the upper surface of substrate 120. As such, die 124 is electrically coupled to die 106, and both die 106 and die 124 are electrically coupled to interconnect joints 122 to connect the PoP package 100 to a further package and/or substrate.

The PoP structure 100 has substantial thermal dissipation limitations, particularly as it relates to the dissipation of heat from any components in the lower package 104. In some examples, the die 106 may include memory components, while die 124 may include logic components. The heat generated by die 124 may be dissipated, at least in part, through the upper package 102. In this example, the PoP structure 100 includes an air gap 128 through which heat from the die 124 is conducted through the interposer substrate 114 to substrate 108 for dissipation at the upper package 102. However, the air is a poor thermal conductor and, as such, limits the heat transfer between the upper package 102 and the lower package 104, causing a heat buildup at the die 124. The operation of the components/circuitry of the die 124 is, therefore, subject to performance limits imposed by the inability of the PoP structure 100 to adequately dissipate heat generated at the die 124. In some scenarios, the components/circuitry of the die 124 must be operated at lower clock rates and/or reduced power to compensate for such inherent thermal dissipation limitations.

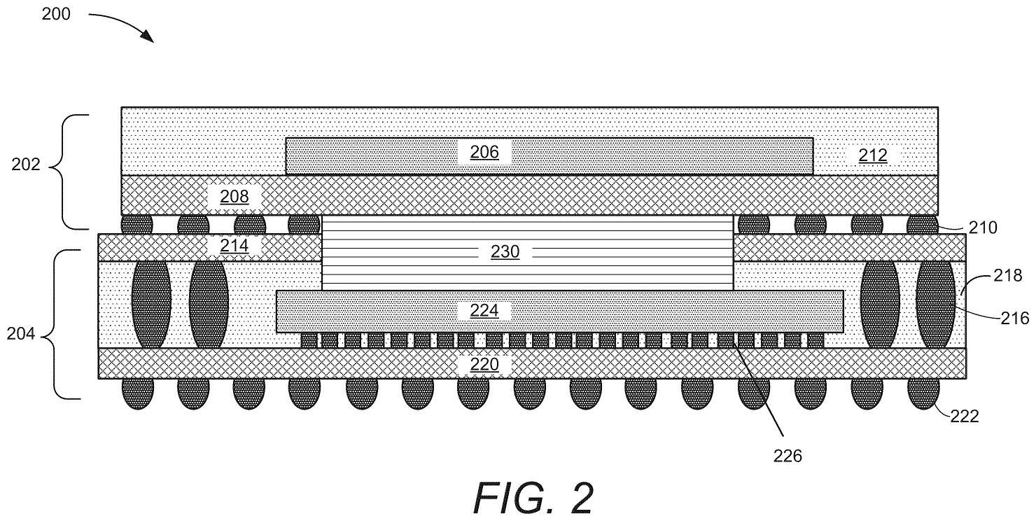

FIG. 2 shows an example of a package-on-package (PoP) structure 200, according to aspects of the disclosure. Again, the patterned metallization layers disposed over various surfaces of the components of the PoP structure 100 and via structures through the substrates have been omitted from the figure for simplicity.

In this example, the PoP structure 200 includes an upper package 202 and a lower package 204. In an aspect, the upper package 202 may include a die 206 that is electrically coupled to one or more patterned metallization layers overlying a substrate 208. In an aspect, the substrate 208 may include via structures that electrically couple the patterned metallization layers overlying the substrate 208 to interconnect joints 210 disposed at a lower surface of the substrate 208. In an aspect, the lower surface of the substrate 208 may include one or more patterned metallization layers. These conductive structures combine to electrically couple the die 206 with the interconnect joints 210. In an aspect, a molding compound 212 may be formed over the die 206 and the upper surface of the substrate 208.

Similarly, the lower package 204 may include an interposer substrate 214 having one or more patterned metallization layers disposed over its upper surface for electrically coupling the interconnect joints 210 to the lower package 204. Another patterned metallization layer may be formed on the lower surface of interposer substrate 214. In an aspect, the interposer substrate 214 may have one or more via structures that electrically couple the patterned metallization layer overlying the interposer substrate 214 to via structures 216 that extend through a molding compound 218 to a patterned metallization layer formed over the upper surface of the interposer 220. In an aspect, the metallization layer formed over the upper surface of the interposer 220 may be electrically coupled to a patterned metallization layer formed over a lower surface of the interposer 220 thereby providing electrically conductive paths between the die 206 and interconnect joints 222 disposed at a lower surface of the interposer 220.

In an aspect, the lower package 204 may include a die 224 having interconnect joints 226 that electrically couple the die 224 to the patterned metallization layer disposed over the upper surface of interposer 220. As such, die 224 is electrically coupled to die 206, and both die 206 and die 224 are electrically coupled to interconnect joints 222 to connect the PoP structure 200 to a further package and/or substrate.

Unlike the PoP 100 of FIG. 1, the PoP structure 200 is augmented with thermal dissipation features, particularly as they relate to the dissipation of heat from components in the lower package 204. In this example, the PoP 200 of FIG. 2 includes a multi-phase cooling structure 230 extending from an upper surface of the die 224 of lower package 204 to a lower surface of the substrate 208 of upper package 202. In an aspect, the multi-phase cooling structure 230 is at least partially bounded at its sides by the interposer substrate 214 and has its upper surface in thermal contact with the lower surface of substrate 208 and its lower surface in thermal contact with the upper surface of the die 224. In an aspect, surfaces may be considered in thermal contact when the surfaces of the allow heat to be conducted between the surfaces. In an aspect, or may be considered in thermal contact even when having an adhesive layer or other bonding material is disposed between the surfaces.

Rather than passing solely through an air gap (e.g., air gap 128 of FIG. 1) between the upper surface of interposer substrate 214 and the lower surface of substrate 208, the heat generated by the die 224 is conducted from the die 224 to the upper package 202 (e.g., at the lower surface of the substrate 208) through a thermally conductive path provided by the multi-phase cooling structure 230. As such, the multi-phase cooling structure 230 provides a more efficient path for heat transfer between the die 224 and the upper package 202, thereby allowing the circuitry of the die 224 (e.g., logic components, system-on-chip (SoC), etc.) to operate at higher clock rates and/or larger power consumption. In an aspect, the components of the die 224 may be formed with a higher component density given the ability of the PoP structure 200 to dissipate a larger amount of heat per unit area.

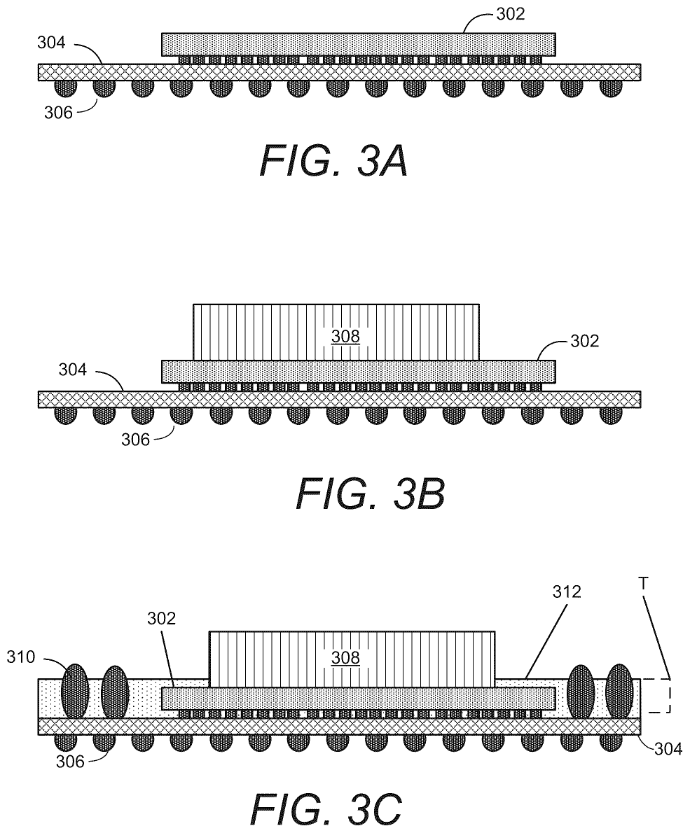

FIG. 3A through FIG. 3E shows example processing operations that may be undertaken to form a PoP structure with augmented heat dissipation, according to aspects of the disclosure. In FIG. 3A, the formation of the lower package may begin with a die 302 disposed over an upper surface of substrate 304. The die 302 is electrically coupled through electrical paths provided by and through the substrate 304 to interconnect joints 306 disposed at the lower surface of the substrate 304.

In FIG. 3B, a multi-phase cooling structure 308 is coupled to the upper surface of the die 302. In an aspect, the lower surface of the multi-phase cooling structure 308 may be coupled to the upper surface of the die 302 with an adhesive, such as a thermal interface material (TIM).

In FIG. 3C, interconnect structures 310 are formed over the upper surface of the substrate 304. A molding compound 312 is disposed over the upper surface of the substrate 304 to a thickness T that covers the die 302 but leaves upper portions of the interconnect structures 310 and multi-phase cooling structure 308 exposed.

In FIG. 3D, an interposer substrate 314 is disposed over the upper surface of the molding compound 312. The interposer substrate 314 at least partially surrounds the side edges of the multi-phase cooling structure 308 while still leaving the upper portion of the multi-phase cooling structure 308 exposed. In an aspect, the processes shown in FIG. 3D completes the formation of a lower package 316.

In FIG. 3E, an upper package 318 is attached to the lower package 316. During this process, the upper surface of the multi-phase cooling structure 308 is placed in thermal contact with the lower surface of the substrate 320 of the upper package 318. In an aspect, the upper surface of the multi-phase cooling structure 308 may be secured to the lower surface of the substrate 320 with an adhesive, such as a TIM. In FIG. 3E, the upper package 318 includes a die 322 disposed over the upper surface of substrate 320. A molding compound 324 is formed over a portion of the upper surface of substrate 320 as well as over the die 322.

It will be understood, based on the teachings of the disclosure, that the substrates 304, 314, and 320 provide any patterned metallization layers and vias needed to electrically couple the die 302 with the die 322 as well as to electrically couple the dies 302, 322 with the interconnect joints 306 at the lower surface of substrate 304.

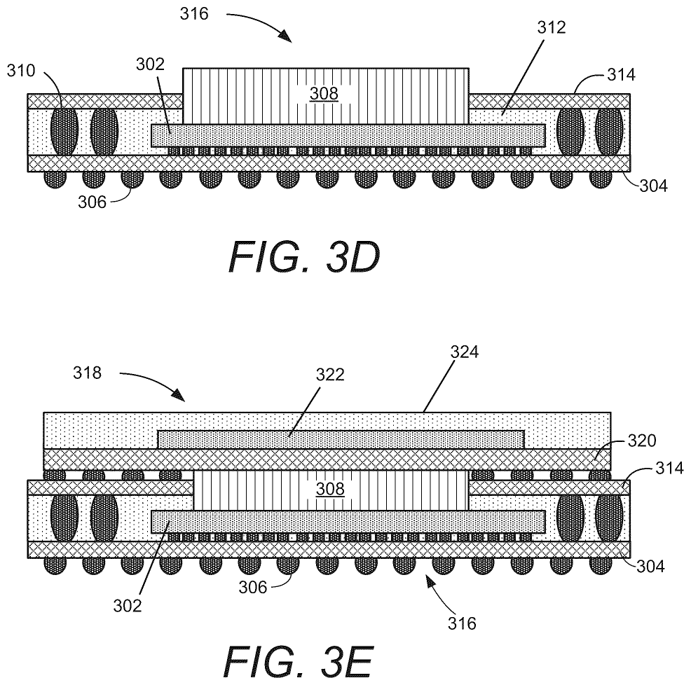

FIG. 4 shows an example of a multi-phase cooling structure, according to aspects of the disclosure. In this example, the multi-phase cooling structure is a two-phase cooling structure 400 that is embodied as a vapor chamber cooling configuration. The two-phase cooling structure 400 uses the phase change of a coolant, such as water, from the liquid state to the vapor state and back to the liquid state to extract and transfer heat to and from various portions of the two-phase cooling structure 400. In this example, the two-phase cooling structure 400 includes a shell 402 having a lower surface 404 configured to receive heat from a heat source (e.g., the die of the lower package) and an upper surface 406 from which the heat may be removed (e.g., the upper package of the PoP structure).

In this example, the vapor chamber cooling structure 400 includes a wick 408 extending from the inner surface of the shell 402 (e.g., copper or other thermally conductive material). In an aspect, the wick 408 may be a porous material lining the inner surface of the shell 402 that facilitates the return of the liquid working fluid from a heat dissipation portion of the vapor chamber cooling structure 400 back to the heat absorption portion of the vapor chamber cooling structure 400 via capillary action.

The coolant travels through the wick 408 in the directions depicted by arrows 410 (not marked in FIG. 4). Heat received at the lower surface 404 heats the coolant traveling through the wick 408, causing the liquid coolant traveling proximate the lower surface 404 to evaporate to a vapor state and enter vapor chamber 412 (not marked in FIG. 4). The vaporized liquid coolant travels through the vapor chamber 412 and contacts the portion of the wick 408 proximate the upper surface 406 where it condenses to the liquid state and releases its heat energy. The released heat energy is transferred through the upper surface 406 where it can be removed from the two-phase cooling structure 400 (e.g., released to the upper package of the PoP structure). After releasing the heat energy, the coolant returns to the liquid state and travels back, via the wick 408, to the lower surface 404, where the evaporation/condensation cycle is repeated.

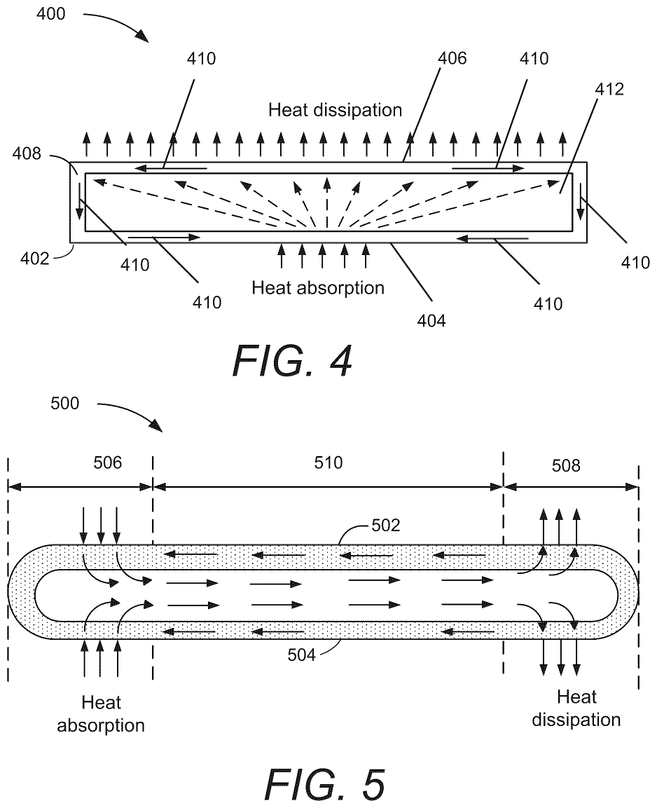

FIG. 5 shows an example of a multi-phase cooling structure, according to aspects of the disclosure. In this example, the multi-phase cooling structure is a two-phase cooling structure 500 that is embodied as a heat pipe cooling configuration. In this example, the two-phase cooling structure 500 includes sealed, hollow tube 502, typically made of Copper or other high thermal conductivity material. Inside the tube 502 is a small amount of a coolant and a wick 504 lining the inner walls of the tube 502. The end 506 of the hollow tube 502 that is in direct contact with the heat source (e.g., die in lower package). In this section coolant is evaporated and absorbs the heat generated by the electronic component. The opposite end 508 of the tube 502, may be connected to a heat sink (e.g., lower surface of the upper package) where the coolant is condensed, and the heat is dispersed. The tube 502 includes a section 510 extending between the heat absorption end 506 and the heat dissipation end 508. In the section 510, the coolant travels back to the end 506 from the end 508, and then repeats the heat transfer cycle.

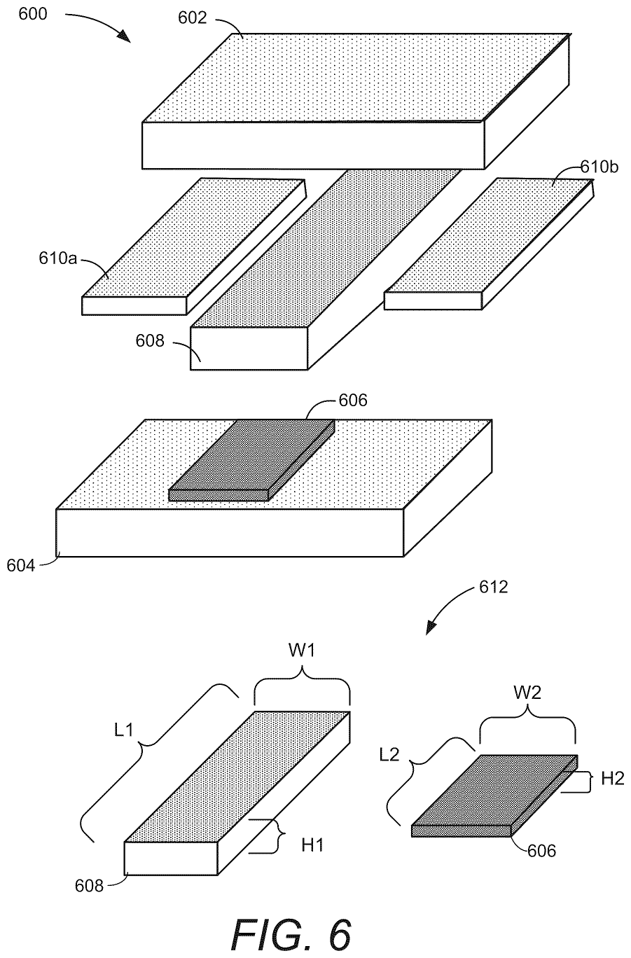

FIG. 6 illustrates an example relationship 600 between certain components used to construct a PoP structure, according to aspects of the disclosure. In this example relationship 600, the components include a substrate 602 of the upper package and a substrate 604 of the lower package on which the die 606 of the lower package is mounted. Here, the multi-phase cooling structure 608 overlies the die 606 and is bounded on each side by a pair of interposer substrates 610a and 610b that extend along the length of the multi-phase cooling structure 608.

The dimensions of an example multi-phase cooling structure 608 and the die 606 are depicted at 612. The example multi-phase cooling structure 608 has a length L1, a width W1, and a height H1. The example die 606 may have a length L2, a width, and a height H2. The cooling structure 608 may be larger in plane than die 606 so that die 606 may be fully covered by cooling structure 608 for optimal heat dissipation.

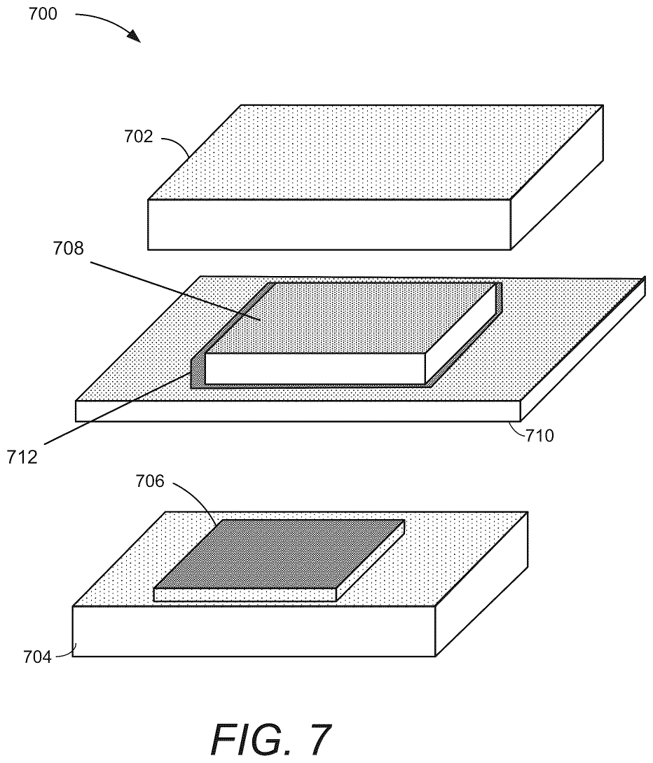

FIG. 7 illustrates another example relationship 700 between certain components used to construct a PoP structure, according to aspects of the disclosure. In this example relationship 700, the components include a substrate 702 of the upper package and a substrate 704 of the lower package on which the die 706 of the lower package is mounted. Here, the multi-phase cooling structure 708 overlies the die 606. Unlike the relationships 600 shown in FIG. 6, the multi-phase cooling structure 708 is bounded on all sides by a single interposer substrate 710. In this relationship 700, the multi-phase cooling structure 708 is disposed in an opening 712 in the interposer substrate 710.

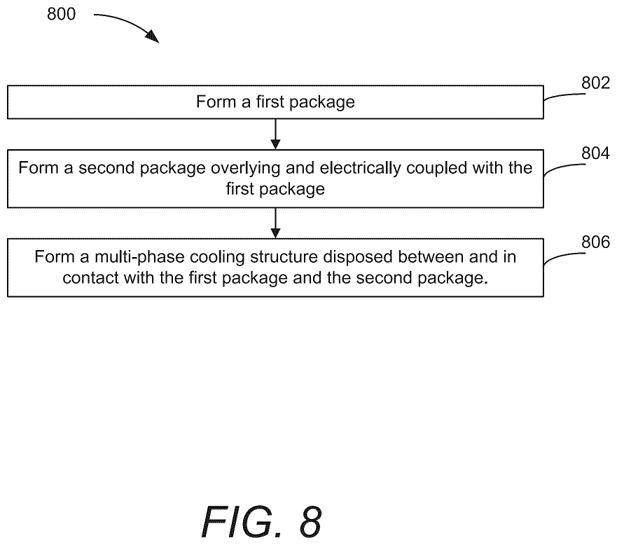

FIG. 8 is a method 800 depicting exemplary steps that may be implemented to form a PoP structure, according to aspects of the disclosure. At operation 802, a first package is formed. At operation 804, a second package overlying and electrically coupled with the first package is formed. At operation 806, a multi-phase cooling structure is formed and disposed between and in thermal contact with the first package and the second package.

A technical advantage of the method 800 is that it may be used to manufacture a PoP structure having improved thermal dissipation characteristics. In an aspect, the multi-phase cooling structure may be used to efficiently transfer heat from the first package to the second package thereby allowing components of the first package to operate 1) at a higher power, 2) at a higher clock rate, and/or 3) with a higher density of components.

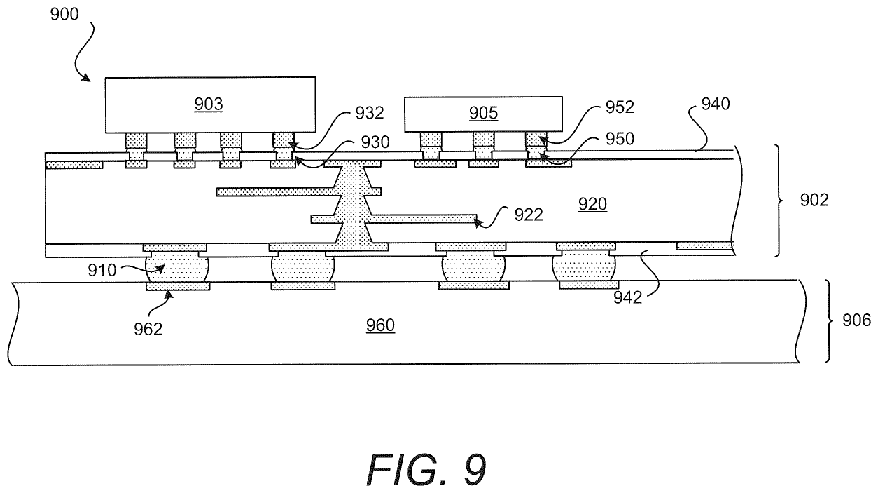

FIG. 9 illustrates a profile view of a package 900 that includes a surface mount substrate 902, an integrated device 903, and an integrated passive device 905, according to aspects of the disclosure. The package 900 may be coupled to a printed circuit board (PCB) 906 through a plurality of solder interconnects 910. The PCB 906 may include at least one board dielectric layer 960 and a plurality of board interconnects 962.

The surface mount substrate 902 includes at least one dielectric layer 920 (e.g., substrate dielectric layer), a plurality of interconnects 922 (e.g., substrate interconnects), a solder resist layer 940 and a solder resist layer 942. The integrated device 903 may be coupled to the surface mount substrate 902 through a plurality of solder interconnects 930. The integrated device 903 may be coupled to the surface mount substrate 902 through a plurality of pillar interconnects 932 and the plurality of solder interconnects 930. The integrated passive device 905 may be coupled to the surface mount substrate 902 through a plurality of solder interconnects 950. The integrated passive device 905 may be coupled to the surface mount substrate 902 through a plurality of pillar interconnects 952 and the plurality of solder interconnects 950.

The package (e.g., 900) may be implemented in a radio frequency (RF) package. The RF package may be a radio frequency front end (RFFE) package. A package (e.g., 900) may be configured to provide Wireless Fidelity (WiFi) communication and/or cellular communication (e.g., 2G, 3G, 4G, 5G). The package (e.g., 900) may be configured to support Global System for Mobile (GSM) Communications, Universal Mobile Telecommunications System (UMTS), and/or Long-Term Evolution (LTE). The package (e.g., 900) may be configured to transmit and receive signals having different frequencies and/or communication protocols.

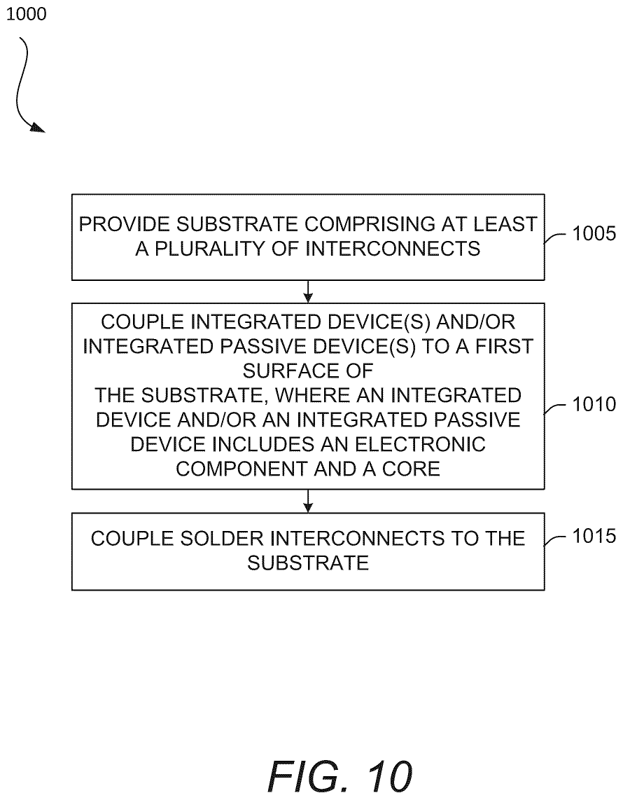

FIG. 10 illustrates an example method 1000 for providing or fabricating a package that includes an integrated device comprising an electronic component mounted in a core, according to aspects of the disclosure. In some implementations, the method 1000 of FIG. 10 may be used to provide or fabricate the package 900 of FIG. 9 described in the disclosure. However, the method 1000 may be used to provide or fabricate any of the packages described in the disclosure.

It should be noted that the method of FIG. 10 may combine one or more processes in order to simplify and/or clarify the method for providing or fabricating a package that includes an integrated device comprising an electronic component mounted in a core, according to aspects of the disclosure. In some implementations, the order of the processes may be changed or modified.

The method provides (at 1005) a substrate (e.g., 902). The substrate 902 may be provided by a supplier or fabricated. The substrate 902 includes at least one dielectric layer 920 and a plurality of interconnects 922. The substrate 902 may include an embedded trace substrate (ETS). In some implementations, the at least one dielectric layer 920 may include prepreg layers.

The method couples (at 1010) at least one integrated device (e.g., 903) to the first surface of the substrate (e.g., 902). For example, the integrated device 903 may be coupled to the substrate 902 through the plurality of pillar interconnects 932 and the plurality of solder interconnects 930. The plurality of pillar interconnects 932 may be optional. The plurality of solder interconnects 930 are coupled to the plurality of interconnects 922. A solder reflow process may be used to couple the integrated device 903 to the plurality of interconnects through the plurality of solder interconnects 930.

The method also couples (at 1010) at least one integrated passive device (e.g., 905) to the first surface of the substrate (e.g., 902). For example, the integrated passive device 905 may be coupled to the substrate 902 through the plurality of pillar interconnects 952 and the plurality of solder interconnects 950. The plurality of pillar interconnects 952 may be optional. The plurality of solder interconnects 950 are coupled to the plurality of interconnects 922. A solder reflow process may be used to couple the integrated passive device 905 to the plurality of interconnects through the plurality of solder interconnects 950.

The method couples (at 1015) a plurality of solder interconnects (e.g., 910) to the second surface of the substrate (e.g., 902). A solder reflow process may be used to couple the plurality of solder interconnects 910 to the substrate.

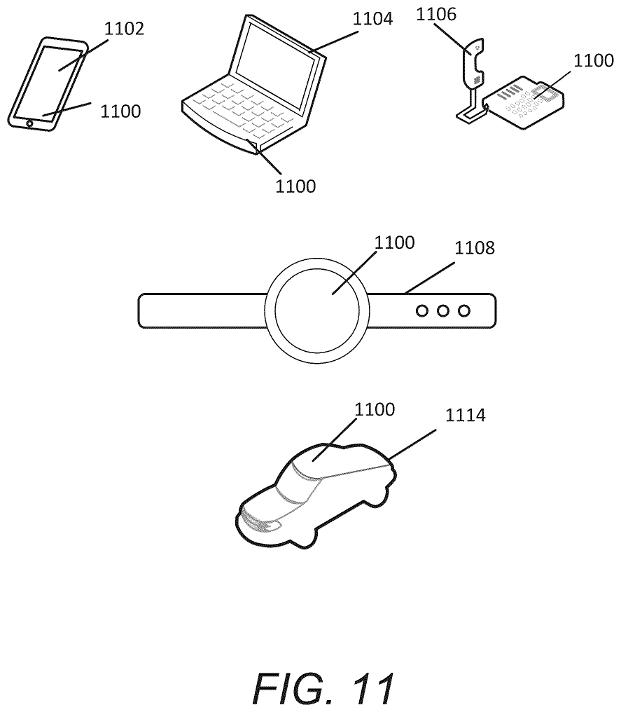

FIG. 11 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC). For example, a mobile phone device 1102, a laptop computer device 1104, a fixed location terminal device 1106, a wearable device 1108, or automotive vehicle 1114 may include a device 1100 as described herein. The device 1100 may be, for example, any of the devices and/or integrated circuit (IC) packages described herein. The devices 1102, 1104, 1106 and 1108 and the vehicle 1110 illustrated in FIG. 11 are merely exemplary. Other electronic devices may also feature the device 1100 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

Implementation examples are described in the following numbered aspects:

Aspect 1. An electronic device, comprising: a package-on-package (PoP) structure comprising: a first package; a second package overlying and electrically coupled with the first package; and a multi-phase cooling structure disposed between and in contact with the first package and the second package.

Aspect 2. The electronic device of aspect 1, wherein: the multi-phase cooling structure comprises a two-phase cooling structure.

Aspect 3. The electronic device of aspect 2, wherein: the two-phase cooling structure comprises a vapor chamber cooling structure.

Aspect 4. The electronic device of any of aspects 2 to 3, wherein: the two-phase cooling structure comprises a heat pipe cooling structure.

Aspect 5. The electronic device of any of aspects 1 to 4, wherein: the first package includes a die having an upper surface in contact with a lower surface of the multi-phase cooling structure.

Aspect 6. The electronic device of aspect 5, wherein: the multi-phase cooling structure is in contact with the upper surface of the die through a thermal interface material.

Aspect 7. The electronic device of aspect 6, wherein: the multi-phase cooling structure is in contact with a lower surface of the second package.

Aspect 8. The electronic device of any of aspects 1 to 7, further comprising: at least one interposer substrate bounding at least a portion of a periphery of the multi-phase cooling structure, wherein the multi-phase cooling structure includes an upper surface extending beyond an upper surface of the at least one interposer substrate to facilitate contact between the upper surface of the multi-phase cooling structure and a lower surface of the second package.

Aspect 9. The electronic device of any of aspects 5 to 8, wherein: the multi-phase cooling structure is in contact with the lower surface of the second package through a thermal interface material.

Aspect 10. The electronic device of any of aspects 1 to 9, wherein: the first package comprises logic components; and the second package includes memory components electrically coupled to the logic components of the first package.

Aspect 11. The electronic device of any of aspects 1 to 10, wherein the electronic device comprises at least one of: a music player; a video player; an entertainment unit; a navigation device; a communication device; a mobile device; a mobile phone; a smartphone; a personal digital assistant; a fixed location terminal; a tablet computer, a computer; a wearable device; a laptop computer; a server; an internet of things (IoT) device; or a device in an automotive vehicle.

Aspect 12. A package-on-package (PoP) structure comprising: a first package; a second package overlying and electrically coupled with the first package; and a multi-phase cooling structure disposed between and in contact with the first package and the second package.

Aspect 13. The PoP structure of aspect 12, wherein: the multi-phase cooling structure comprises a two-phase cooling structure.

Aspect 14. The PoP structure of aspect 13, wherein: the two-phase cooling structure comprises a vapor chamber cooling structure.

Aspect 15. The PoP structure of any of aspects 13 to 14, wherein: the two-phase cooling structure comprises a heat pipe cooling structure.

Aspect 16. The PoP structure of any of aspects 12 to 15, wherein: the first package includes a die having an upper surface in contact with a lower surface of the multi-phase cooling structure.

Aspect 17. The PoP structure of aspect 16, wherein: the multi-phase cooling structure is in contact with the upper surface of the die through a thermal interface material.

Aspect 18. The PoP structure of aspect 17, wherein: the multi-phase cooling structure is in contact with a lower surface of the second package.

Aspect 19. The PoP structure of any of aspects 12 to 18, further comprising: at least one interposer substrate bounding at least a portion of a periphery of the multi-phase cooling structure, wherein the multi-phase cooling structure includes an upper surface extending beyond an upper surface of the at least one interposer substrate to facilitate contact between the upper surface of the multi-phase cooling structure and a lower surface of the second package.

Aspect 20. A method of forming a package-and-package (PoP) structure, comprising: forming a first package; forming a second package overlying and electrically coupled with the first package; and forming a multi-phase cooling structure disposed between and in contact with the first package and the second package.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on the bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a patterned metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more patterned metallization layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the detailed description above, it can be seen that different features are grouped together in examples. This manner of disclosure should not be understood as an intention that the example aspects have more features than are explicitly mentioned in each aspect. Rather, the various aspects of the disclosure may include fewer than all features of an individual example aspect disclosed. Therefore, the following aspects should hereby be deemed to be incorporated in the description, wherein each aspect by itself can stand as a separate example. Although each dependent aspect can refer in the aspects to a specific combination with one of the other aspects, the aspect(s) of that dependent aspect are not limited to the specific combination. It will be appreciated that other example aspects can also include a combination of the dependent aspect(s) with the subject matter of any other dependent aspect or independent aspect or a combination of any feature with other dependent and independent aspects. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of an aspect can be included in any other independent aspect, even if the aspect is not directly dependent on the independent aspect.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An electronic device, comprising:
a package-on-package (PoP) structure comprising:
a first package;
a second package overlying and electrically coupled with the first package; and
a multi-phase cooling structure disposed between and in contact with the first package and the second package.

2. The electronic device of claim 1, wherein:
the multi-phase cooling structure comprises a two-phase cooling structure.

3. The electronic device of claim 2, wherein:
the two-phase cooling structure comprises a vapor chamber cooling structure.

4. The electronic device of claim 2, wherein:
the two-phase cooling structure comprises a heat pipe cooling structure.

5. The electronic device of claim 1, wherein:
the first package includes a die having an upper surface in contact with a lower surface of the multi-phase cooling structure.

6. The electronic device of claim 5, wherein:
the multi-phase cooling structure is in contact with the upper surface of the die through a thermal interface material.

7. The electronic device of claim 6, wherein:
the multi-phase cooling structure is in contact with a lower surface of the second package.

8. The electronic device of claim 1, further comprising:
at least one interposer substrate bounding at least a portion of a periphery of the multi-phase cooling structure, wherein the multi-phase cooling structure includes an upper surface extending beyond an upper surface of the at least one interposer substrate to facilitate contact between the upper surface of the multi-phase cooling structure and a lower surface of the second package.

9. The electronic device of claim 5, wherein:
the multi-phase cooling structure is in contact with the lower surface of the second package through a thermal interface material.

10. The electronic device of claim 1, wherein:
the first package comprises logic components; and
the second package includes memory components electrically coupled to the logic components of the first package.

11. The electronic device of claim 1, wherein the electronic device comprises at least one of:
a music player;
a video player;
an entertainment unit;
a navigation device;
a communication device;
a mobile device;
a mobile phone;
a smartphone;
a personal digital assistant;
a fixed location terminal;
a tablet computer, a computer;
a wearable device;
a laptop computer;
a server;
an internet of things (IoT) device; or
a device in an automotive vehicle.

12. A package-on-package (PoP) structure comprising:
a first package;
a second package overlying and electrically coupled with the first package; and
a multi-phase cooling structure disposed between and in contact with the first package and the second package.

13. The PoP structure of claim 12, wherein:
the multi-phase cooling structure comprises a two-phase cooling structure.

14. The PoP structure of claim 13, wherein:
the two-phase cooling structure comprises a vapor chamber cooling structure.

15. The PoP structure of claim 13, wherein:
the two-phase cooling structure comprises a heat pipe cooling structure.

16. The PoP structure of claim 12, wherein:
the first package includes a die having an upper surface in contact with a lower surface of the multi-phase cooling structure.

17. The PoP structure of claim 16, wherein:
the multi-phase cooling structure is in contact with the upper surface of the die through a thermal interface material.

18. The PoP structure of claim 17, wherein:
the multi-phase cooling structure is in contact with a lower surface of the second package.

19. The PoP structure of claim 12, further comprising:
at least one interposer substrate bounding at least a portion of a periphery of the multi-phase cooling structure, wherein the multi-phase cooling structure includes an upper surface extending beyond an upper surface of the at least one interposer substrate to facilitate contact between the upper surface of the multi-phase cooling structure and a lower surface of the second package.

20. A method of forming a package-and-package (PoP) structure, comprising:
forming a first package;
forming a second package overlying and electrically coupled with the first package; and
forming a multi-phase cooling structure disposed between and in contact with the first package and the second package.
